(19) United States
(12) Patent Application Publication
(10) Pub. No.: US 2026/0215317 A1
(43) Pub. Date: Jul. 23, 2026

(54) INTEGRATED CIRCUIT

(71) Applicant: Pragmatic Semiconductor Ltd, Cambridge (GB)

(72) Inventors: Brian COBB, Cambridge (GB); Richard PRICE, Cambridge (GB); Feras ALKHALIL, Cambridge (GB); Ken WILLIAMSON, Cambridge (GB)

(21) Appl. No.: 19/569,829

(22) Filed: Mar. 17, 2026

Related U.S. Application Data
(63) Continuation of application No. PCT/GB2024/052414, filed on Sep. 18, 2024.

(30) Foreign Application Priority Data
Sep. 20, 2023 (GB) 2314405.8

(51) Int. Cl. H10W 72/30; H10W 72/00; H10W 72/90; H10W 90/00; H10W 90/28

(52) U.S. Cl. CPC H10W 72/334; H10W 72/337; H10W 72/342; H10W 72/347; H10W 72/934; H10W 72/9415; H10W 90/28; H10W 90/732; H10W 72/01323; H10W 72/07338

(57) ABSTRACT

An electronic circuit assembly comprising an application circuit comprising a plurality of application circuit electrical contact pads; and a flexible integrated circuit comprising a first surface, a second surface on an opposite face of the flexible integrated circuit to the first surface, and a plurality of integrated circuit electrical contact pads located on the second surface. The flexible integrated circuit is arranged such that the first surface faces the application circuit and each of the application circuit electrical contact pads is located at least partially outside of a footprint of the flexible integrated circuit. Each of the integrated circuit electrical contact pads is electrically connected to a respective one of the application circuit electrical contact pads by a respective one of a plurality of solidified fluid conductors.

### CROSS-REFERENCE TO RELATED APPLICATIONS

This application is a Continuation of PCT Patent Application No. PCT/GB2024/052414 having International filing date of Sep. 18, 2024, which claims the benefit of priority of United Kingdom Application No. GB 2314405.8 filed on Sep. 20, 2023. The contents of the above applications are all incorporated by reference as if fully set forth herein in their entirety.

### TECHNICAL FIELD

The present disclosure concerns flexible integrated circuits. More particularly, but not exclusively, this disclosure concerns electronic circuit assemblies including flexible integrated circuits and methods of manufacturing such electronic circuit assemblies. The disclosure also concerns flexible integrated circuits and methods of manufacturing flexible integrated circuits.

### BACKGROUND

Integrated circuits are an essential part of many electrical systems. In such systems, the integrated circuit (IC) is generally connected to an application circuit to form an electronic circuit assembly. It will be appreciated by the skilled person that the term application circuit refers to a circuit which is external to the integrated circuit and is arranged to connect to and operate with the integrated circuit. For example, an application circuit may comprise a printed circuit board (PCB) onto which the integrated circuit is mounted.

Signals and power flow between the integrated circuit and the application circuit via a plurality of integrated circuit electrical contact pads on the integrated circuit and a corresponding plurality of application circuit electrical contact pads on the application circuit. A conductor (typically solder) bonds each of the integrated circuit electrical contact pads to a respective one of the application circuit electrical contact pads, enabling the transfer of signals and / or power between the integrated circuit and the application circuit via the integrated circuit electrical contact pad, the conductor, and the application circuit electrical contact pad.

Typically, integrated circuits are formed with electrical contact pads on an external bonding surface of the integrated circuit. The external bonding surface is the surface of the integrated circuit that, when the integrated circuit is mounted on the application circuit, faces the application circuit. The application circuit electrical contact pads are arranged on a bonding surface of the application circuit in a pattern which mirrors that of the integrated circuit electrical contact pads. During assembly, the integrated circuit is placed onto the application circuit with the external bonding surface of the integrated circuit facing the bonding surface of the application circuit, such that the integrated circuit electrical contact pads are brought into alignment with the application circuit electrical contact pads. Typically, solder paste or anisotropic conductive adhesive (ACA) is used to provide electrical connection (and mechanical bonding) of each integrated circuit electrical contact pad to the corresponding application circuit electrical contact pad. Examples of such integrated circuit packages include a ball grid array (BGA), a land grid array (LGA), and a pin grid array (PGA).

Flexible integrated circuits (FlexICs) are generally much thinner and more flexible than conventional integrated circuits, enabling them to be used in a wider range of applications. However, the thinner and more flexible structure of a flexible integrated circuit can present issues not encountered by conventional integrated circuits. For example, in a flexible integrated circuit the internal circuitry of the integrated circuit can be sufficiently close to the external bonding surface of the flexible integrated circuit that the hard conducting particles (for example, nickel particles) in ACA can pierce the external bonding surface and make contact with the internal circuitry. This can damage the flexible integrated circuit (for example, by causing a short circuit in the internal circuitry), resulting in an increased failure rate and reduced manufacturing yields.

The present disclosure seeks to mitigate the above-mentioned problems. Alternatively or additionally, the present disclosure seeks to provide an improved electronic circuit assembly or flexible integrated circuit. Alternatively or additionally, the present disclosure seeks to provide an improved method of manufacturing an electronic circuit assembly or flexible integrated circuit.

### SUMMARY

The present disclosure provides, according to a first aspect, an electronic circuit assembly comprising:
an application circuit comprising a plurality of application circuit electrical contact pads; and
a flexible integrated circuit comprising a first surface, a second surface on an opposite face of the flexible integrated circuit to the first surface, and a plurality of integrated circuit electrical contact pads located on the second surface;
wherein:
the flexible integrated circuit is arranged such that the first surface faces the application circuit and each of the application circuit electrical contact pads is located at least partially outside of a footprint of the flexible integrated circuit; and
each of the integrated circuit electrical contact pads is electrically connected to a respective one of the application circuit electrical contact pads by a respective one of a plurality of solidified fluid conductors.

According to a second aspect of the disclosure there is also provided a method of manufacturing an electronic circuit assembly, the method comprising:
providing an application circuit having a plurality of application circuit electrical contact pads; and
providing a flexible integrated circuit comprising a first surface, a second surface on an opposite face of the integrated circuit to the first surface, and a plurality of integrated circuit electrical contact pads located on the second surface;
positioning the flexible integrated circuit on the application circuit such that the first surface faces the application circuit and at least part of each of the application circuit electrical contact pads is outside of a footprint of the flexible integrated circuit; and
depositing conductive fluid across at least part of the second surface to electrically connect each of the integrated circuit electrical contact pads to a respective one of the application circuit electrical contact pads.

According to a third aspect of the disclosure there is also provided a flexible integrated circuit comprising:
an upper dielectric layer;
a lower dielectric layer;
an electrical routing layer located between the upper dielectric layer and the lower dielectric layer; and
an edge connection tab which is electrically coupled to the electrical routing layer and protrudes beyond a footprint of the upper dielectric layer.

According to a fourth aspect of the disclosure there is also provided a method of manufacturing an electronic circuit assembly, the method comprising:
providing an application circuit comprising a metal protrusion;
providing a flexible integrated circuit comprising:
   an upper dielectric layer;
   a lower dielectric layer;
   an electrical routing layer located between the upper dielectric layer and the lower dielectric layer; and
   an edge connection tab which is electrically coupled to the electrical routing layer and protrudes beyond a footprint of the upper dielectric layer; and
electrically coupling the electrical routing layer to the metal protrusion by pressing the edge connection tab down onto the protrusion.

According to a fifth aspect of the disclosure there is also provided a method of manufacturing flexible integrated circuits, the method comprising:
providing on a manufacturing carrier a plurality of flexible integrated circuits, each of the flexible integrated circuits comprising an upper dielectric layer, a lower dielectric layer, and an electrical routing layer located between the upper dielectric layer and the lower dielectric layer;
plating the manufacturing carrier and the plurality of flexible integrated circuits with a conductive layer; and
separating the plurality of flexible integrated circuits by cutting through the conductive layer between the flexible integrated circuits,
wherein the plurality of flexible integrated circuits are spaced apart on the manufacturing carrier such that the cutting forms, on each of the flexible integrated circuits, an edge connection tab comprising an extension of the conductive layer beyond a footprint of the respective upper dielectric layer.

It will of course be appreciated that features described in relation to one aspect of the present disclosure may be incorporated into other aspects of the present disclosure. For example, the method of the disclosure may incorporate any of the features described with reference to the apparatus of the disclosure and vice versa.

### BRIEF DESCRIPTION OF THE DRAWINGS

Embodiments of the present disclosure will now be described by way of example only with reference to the accompanying schematic drawings of which:

FIG. 1 shows a schematic view of an electronic circuit assembly according to the present disclosure;

FIG. 2 shows a schematic view of an electronic circuit assembly according to the present disclosure;

FIG. 3 shows a schematic view of an electronic circuit assembly according to the present disclosure;

FIG. 4 shows a schematic view of an electronic circuit assembly according to the present disclosure;

FIG. 5 shows a schematic view of an electronic circuit assembly according to the present disclosure;

FIG. 6 shows a flow chart illustrating the steps of a method according to the present disclosure;

FIG. 7 shows a schematic view of a flexible integrated circuit according to the present disclosure;

FIG. 8 shows a schematic view of a flexible integrated circuit according to the present disclosure;

FIG. 9 shows a schematic view of a flexible integrated circuit according to the present disclosure;

FIG. 10 shows a schematic view of a flexible integrated circuit according to the present disclosure;

FIG. 11 shows a schematic view of an electronic circuit assembly according the present disclosure;

FIG. 12 shows a schematic view of an electronic circuit assembly according the present disclosure

FIG. 13 shows a flow chart illustrating the steps of a method according to the present disclosure;

FIG. 14 shows a flow chart illustrating the steps of a method according to the present disclosure; and

FIG. 15 shows a schematic view of an intermediate stage in the method of FIG. 14.

### DETAILED DESCRIPTION

The present disclosure is, at least in part, based on a recognition by the inventors that the distinct form factor of flexible integrated circuits enables the use of new and improved methods for assembling electronic circuit assemblies incorporating flexible integrated circuits.

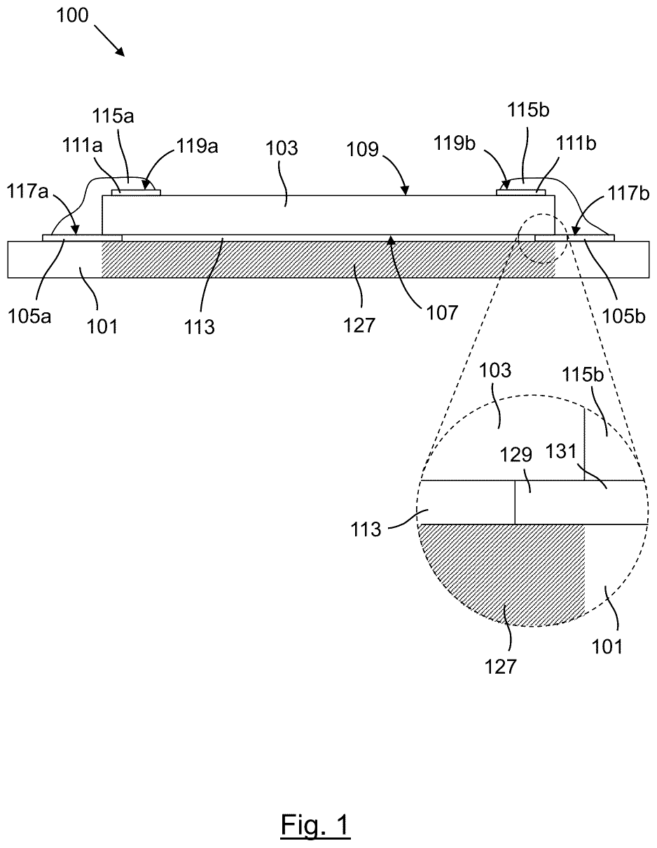

FIG. 1 shows a schematic view of an electronic circuit assembly 100 according to the present disclosure, including a magnified portion of electronic circuit assembly 100. Electronic circuit assembly 100 comprises an application circuit 101 and a flexible integrated circuit 103. It may be that flexible integrated circuit 103 comprises a thin-film flexible integrated circuit.

Application circuit 101 may comprise a larger circuit of which flexible integrated circuit 103 is to form part. For example, application circuit 101 may comprise one or more of an antenna, a printed circuit board, or another integrated circuit, or any other suitable application circuit (for example, a flexible integrated circuit or an application-specific integrated circuit).

Application circuit 101 comprises a plurality of application circuit electrical contacts or contact pads 105a, 105b. Whilst the examples illustrated by FIG. 1 show only two application circuit electrical contact pads, it will be appreciated by the skilled person that application circuit 101 may include any number of application circuit electrical contacts or contact pads. It may be that one or more (for example, all) of application circuit electrical contact pads 105a, 105b are formed of conductive material. The conductive material may comprise metal (for example, one or more of copper, gold, aluminium, or any other metal).

In accordance with the present disclosure a “flexible integrated circuit” (flexible IC or flexIC) is a type of integrated circuit that is designed to be flexible and conformable, allowing it to bend, twist, and conform to non-flat or irregular surfaces. Unlike traditional rigid ICs, which are typically made on silicon wafers and are inflexible, flexible ICs, in accordance with the present disclosure, are fabricated on flexible substrates using appropriate materials and thin-film processes. The substrate is typically formed of an appropriate flexible polymer material. Nevertheless, the flexible substrate may be formed from any other materials that provide suitable electrical, chemical, and/or structural properties. The flexible substrate may be formed from a single common material, may be formed from a plurality of different materials, or may be formed from a plurality of different types of the same material. The flexible substrate may, for example, comprise one or more materials selected from the following list of materials:
flexible glass, polymer materials, metal oxide materials, resin materials, resist materials, foil materials, paper, insulator coated metals, or any other suitable material.

Where a polymer based material is used, the substrate may comprise one or more polymers selected from: polyethylene naphthalates, polyethylene terephthalates; polymethyl methacrylates; polycarbonates, polyvinyl alcohols, polyvinyl acetates, polyvinyl pyrrolidones, polyvinyl phenols, polyvinyl chlorides, polystyrenes, polyimides, polyamides (e.g. Nylon); poly(hydroxy ethers), polyurethanes, polycarbonates, polysulfones, parylenes, polyarylates, polyether ether ketones (PEEKs); acrylonitrile butadiene styrene (ABS), 1 Methoxy 2 propyl acetates, Benzocyclobutenes (BCB), polylactic acid (PLA), polyhydroxyalkanoates (PHAs), polybutylene succinate (PBS), polybutylene adipate terephthalate (PBAT), cellulose polymers, or any other suitable polymer material.

Where a metal oxide based material is used, the substrate may comprise one or more metal oxides selected from: Al₂O₃, SiOₓN_{y}, SiO₂, Si₃N₄, or any other suitable metal oxide. Where a resin based material is used, the substrate may comprise one or more resins selected from: a UV-curable resin or any other suitable resin. Where a resist based material is used, the substrate may comprise one or more resists selected from: nanoimprint resists, photoresists such as, for example, Bisphenol A novolac epoxy (SU-8) or polyhydroxybenzyl silsesquioxane, or any other suitable resist. Where a foil based material is used the substrate may comprise one or more foils selected from: polymeric foils or any other suitable foil. Where an insulator-coated metal is used, the substrate may comprise one or more insulator-coated metals selected from: insulator coated stainless-steel or any other suitable insulator-coated metal.

Additionally or alternatively, a flexible IC may not include the flexible substrate, which, for example, may be removed prior to assembly onto an application circuit.

Flexible integrated circuit 103 comprises a first surface 107 and a second surface 109. Second surface 109 is located on an opposite face of flexible integrated circuit 103 to first surface 107. First surface 107 can be said to comprise an inner surface of flexible integrated circuit 103. Second surface 109 can be said to comprise an outer surface of flexible integrated circuit 103. Thus, when flexible integrated circuit 103 is mounted on application circuit 101, first surface 107 faces application circuit 101 and second surface 109 faces away from application circuit 101. It will be appreciated by the skilled person that first surface 107 is referred to as the “inner” surface because it forms a mating surface with a corresponding portion of application circuit 101. The surface area of application circuit 101 covered by flexible integrated circuit 103 can be referred to as a footprint of flexible integrated circuit 103 (illustrated by hatched region 127).

Flexible integrated circuit 103 further comprises a plurality of integrated circuit electrical contact pads 111a, 111b located on second surface 109. Flexible integrated circuit 103 may comprise an equal number of integrated circuit electrical contact pads 111a, 111b to the number of application circuit electrical contact pads 105a, 105b. For example, it may be that there is a one-to-one correspondence of integrated circuit electrical contact pads 111a, 111b to application circuit electrical contact pads 105a, 105b, such that each integrated circuit electrical contact pad is associated with a respective application circuit electrical contact pad. Alternatively, more than one of integrated circuit electrical contact pads 111a, 111b may be associated with a single one of application circuit electrical contact pads 105a, 105b. Similarly, more than one of application circuit electrical contact pads 105a, 105b may be associated with a single one of integrated circuit electrical contact pads 111a, 111b. It may be that flexible integrated circuit 103 does not include any electrical contact pads on first surface 107. Thus, it may be that first surface 107 is formed entirely of dielectric material. Providing electrical contact pads on second surface 109 means that the electrical contact pads are formed on the upper surface of flexible integrated circuit 103 (i.e. the surface that faces away from application circuit 101 when flexible integrated circuit 103 is mounted to application circuit 101). This can allow first surface 107 to be completely free of conductive material, which in turn enables application circuit 101 to incorporate conductive tracks or other conductive structures within the footprint of flexible integrated circuit 103 without the risk of a short circuit or the need for an additional layer of insulating material between flexible integrated circuit 103 and application circuit 101.

Whilst the examples illustrated by FIG. 1 show only two integrated circuit electrical contact pads 111a, 111b, it will be appreciated by the skilled person that flexible integrated circuit 103 may include any number of integrated circuit electrical contact pads. One or more (for example, all) of integrated circuit electrical contact pads 111a, 111b may be formed of conductive material. Conductive materials may be selected from one or more of: metals, metal alloys, transparent conductive oxides, metal nitrides, carbon materials, conducting polymers, semiconductor materials, or any other suitable conductive material. For example, conductive materials may be selected from one or more of: metals such as Au, Ti, Al, Mo, Pt, Pd, Ag, Cu, Ni, Cr, Ta, W or any other suitable metal; metal alloys such as MoNi, MoCr, AlSi or any other suitable metal alloys; transparent conductive oxides such as ITO, IZO, AZO, or any other suitable transparent conductive oxide; metal nitrides such as TiN or any other suitable metal nitride; carbon materials such as carbon black, carbon nanotubes, graphene or any other suitable carbon material; conducting polymers such as polyaniline, poly(3,4-ethylenedioxythiophene) polystyrene sulfonate (PEDOT:PSS) or any other suitable conducting polymer.

Where the conductive material comprises a semiconductor material, the semiconductor material may be selected from one or more of: compound semiconductors, metal oxides, metal oxynitrides, inorganic semiconductors, organic semiconductors, polymer semiconductors, 2D semiconductor materials, chalcogenides, perovskites, or any other semiconductor material. For example, semiconductor materials may be selected from one or more of: GaAs, GaN, InP, CdSe, InGaAs, InGaAsSb, ZnO, SnO₂, NiO, SnO, Cu₂O, In₂O₃, LiZnO, ZnSnO, InSnO (ITO), InZnO (IZO), HfInZnO (HIZO), InGaZnO (IGZO) ZnₓO_{y}N_{z} amorphous, microcrystalline or nanocrystalline Si, Copper(II) phthalocyanine (CuPc), pentacene, Perylenetetracarboxylic dianhydride (PTCDA), methylene blue, Orange G, rubrene; PEDOT:PSS, poly(3-octylthiophene) (POT), poly(3-octylthiophene-2,5-diyl) (P3OT), poly(3-hexylthiophene) (P3HT), polyaniline, polycarbazole, grapheneMoS₂, GeSbTeSrTiO₃, CH₃NH₃PbCl₃, H₂NCHNH₂PbCl₃, CsSnI₃, or any other suitable semiconductor material.

Flexible integrated circuit 103 is arranged on application circuit 101 such that first surface 107 faces application circuit 101. First surface 107 may be adjacent to (for example, abut) application circuit 101. Thus, it may be that first surface 107 is in direct contact with application circuit 101. There may be a layer of adhesive 113 (for example, non-conductive adhesive) located between first surface 107 and the application circuit 101 (for example, for the purpose of mechanically bonding flexible integrated circuit 103 to application circuit 101).

The arrangement of flexible integrated circuit 103 on application circuit 101 may be such that one or more (for example, all) of application circuit electrical contact pads 105a, 105b are located at least partially outside of the footprint of flexible integrated circuit 103. One or more of application circuit electrical contact pads 105a, 105b may be located at least partially within the footprint of flexible integrated circuit 103. Thus, it may be that one or more of application circuit electrical contact pads 105a, 105b protrude outwards from beneath flexible integrated circuit 103. A first portion 129 of the one or more application circuit electrical contact pads 105a, 105b may be located between first surface 107 and application circuit 101 (i.e. within the footprint of flexible integrated circuit 103). In such cases, it may be that a second portion 131 of the one or more application circuit electrical contact pads 105a, 105b is located outside of the footprint of flexible integrated circuit 103.

Electronic circuit assembly 100 further comprises a plurality of solidified fluid conductors 115a, 115b. Solidified fluid conductors 115a, 115b may have been formed by depositing conductive fluid. Thus, it may be that solidified fluid conductors 115a, 115b comprise solidified conductive fluid. The conductive fluid may, for example, comprise conductive ink, solder, or any other conductive fluid comprising any of the aforementioned conductive materials such as, for example, a precursor solvent comprising any of the aforementioned conductive materials. Solidified fluid conductors 115a, 115b may have been formed by printing (for example, ink-jet printing, such as “thermal bubble” or “bubble jet” printing, or screen printing) the conductive fluid. Solidified fluid conductors 115a, 115b may have been formed by depositing the conductive fluid using a syringe. Solidified fluid conductors 115a, 115b may have been formed by depositing the conductive fluid using direct write processes.

Each of integrated circuit electrical contact pads 111a, 111b may be electrically connected to associated application circuit electrical contact pads 105a, 105b by a respective one of solidified fluid conductors 115a, 115b. FIG. 1 shows only two solidified fluid conductors 115a, 115b. However, it will be appreciated by the skilled person that electronic circuit assembly 100 may include any number of solidified fluid conductors 115a, 115b. Electronic circuit assembly 100 may comprise an equal number of solidified fluid conductors 115a, 115b to the number of integrated circuit electrical contact pads 111a, 111b and application circuit electrical contact pads 105a, 105b (for example, where the electronic assembly has a one-to-one correspondence of integrated circuit electrical contact pads 111a, 111b to application circuit electrical contact pads 105a, 105b). Alternatively, where more than one of integrated circuit electrical contact pads 111a, 111b is associated with a single application circuit contact pad, it may be that a single solidified fluid conductor connects multiple integrated circuit electrical contact pads 111a, 111b to a single application circuit electrical contact pad 105a, 105b or a single integrated circuit electrical contact pad 111a, 111b to multiple application circuit electrical contact pads 105a, 105b.

One or more (for example, all) of solidified fluid conductors 115a, 115b may extend along a side of flexible integrated circuit 103. Thus, one or more (for example, all) of solidified fluid conductors 115a, 115b may be in direct contact with a side of flexible integrated circuit 103. It will be appreciated by the skilled person that integrated circuits generally have a substantially planar structure; which is to say that they are generally shaped as a flattened cuboid. Thus, integrated circuits generally have two larger parallel faces and four smaller narrow side faces. One of the two larger faces, referred to as an “inner” surface, faces towards an application circuit when mounted to the application circuit. The other opposing surface (i.e. the one which faces away from the application circuit when the integrated circuit is mounted to the application circuit) is referred to as the “outer” surface. The term “side” in this context refers to the four narrow faces which adjoin both the inner and outer surfaces.

Electrically connecting integrated circuit electrical contact pads 111a, 111b to application circuit electrical contact pads 105a, 105b using solidified fluid conductors 115a, 115b can provide an inexpensive and quick way of integrating a flexible integrated circuit with an application circuit.

One or more (for example, all) of solidified fluid conductors 115a, 115b may extend beyond a footprint of flexible integrated circuit 103. One or more (for example, all) of solidified fluid conductors 115a, 115b may extend across at least part of second surface 109.

Each of application circuit electrical contact pads 105a, 105b may comprise an application circuit connection surface 117a, 117b. Thus, it may be that a first application circuit electrical contact pad 105a comprises a first application circuit connection surface 117a. Similarly, it may be that a second application circuit electrical contact pad 105b comprises a second application circuit connection surface 117b. Each of integrated circuit electrical contact pads 111a, 111b may comprise an integrated circuit connection surface 119a, 119b. Thus, it may be that a first integrated circuit electrical contact pad 111a comprises a first integrated circuit connection surface 119a. Similarly, it may be that a second integrated circuit electrical contact pad 111b comprises a second integrated circuit connection surface 119b. Solidified fluid conductors 115a, 115b may connect each of application circuit electrical contact pads 105a, 105b to the respective integrated circuit electrical contact pad 111a, 111b via the respective application circuit connection surface 117a, 117b and integrated circuit connection surface 119a, 119b. Thus, it may be that the first integrated circuit electrical contact pad 111a is connected to the first application circuit electrical contact pad 105a by a first solidified fluid conductor 115a. Similarly, it may be that the second integrated circuit electrical contact pad 111b is connected to the second application circuit electrical contact pad 105b by a second solidified fluid conductor 115b. One or more (for example, all) of application circuit electrical contact pads 105a, 105b may have application circuit connection surfaces 117a, 117b of which at least part (for example, all of which) is parallel to second surface 109. One or more (for example, all) of integrated circuit electrical contact pads 111a, 111b may have integrated circuit connection surfaces 119a, 119b of which at least part (for example, all of which) is parallel to second surface 109.

For one or more of application circuit electrical contact pads 105a, 105b, the application circuit connection surfaces 117a, 117b may be located within a given plane. The plane may be located towards the application circuit from the second surface. Thus, it may be that the one or more application circuit electrical contact pads 105a, 105b are located on the same side of second surface 109 as flexible integrated circuit 103. The application circuit connection surfaces 117a, 117b of one or more of the application circuit electrical contact pads 105a, 105b may be substantially coplanar (for example, coplanar) with first surface 107. It will be appreciated by the skilled person that substantially coplanar includes an arrangement in which first surface 107 abuts the application circuit electrical contact pads 105a, 105b.

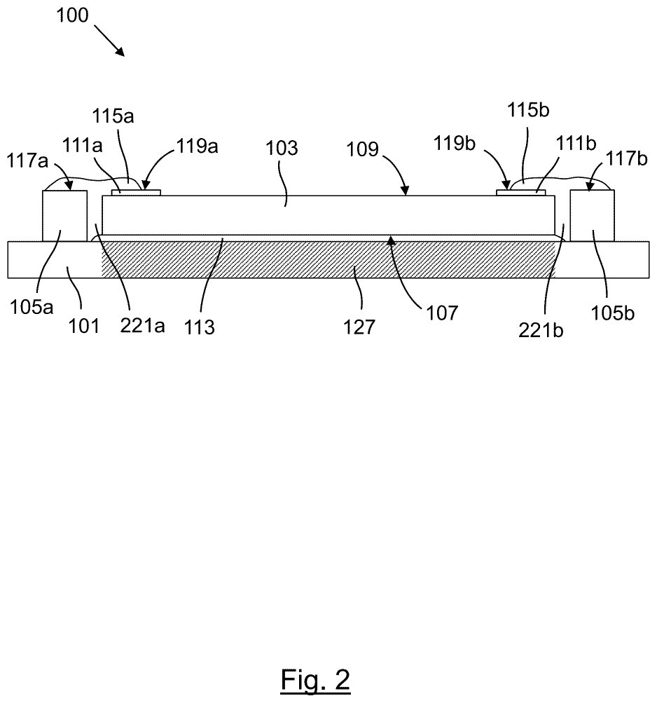

FIG. 2 shows a schematic view of an electronic circuit assembly according to the present disclosure. As shown in FIG. 2, the application circuit connection surfaces 117a, 117b of one or more of application circuit electrical contact pads 105a, 105b may be substantially coplanar (for example, coplanar) with integrated circuit connection surfaces 119a, 119b. Thus, it may be that the application circuit electrical contact pads 105a, 105b protrude above a surface of application circuit 101 by an equal distance to that protruded by flexible integrated circuit 103. The application circuit electrical contact pads 105a, 105b may protrude above a surface of application circuit 101 by a distance equal to a height of flexible integrated circuit 103. It will be appreciated by the skilled person that the distance protruded by flexible integrated circuit 103 above a surface of application circuit 101 is not in all cases the same as the height of flexible integrated circuit 103, as in some cases the flexible integrated circuit may not directly abut application circuit 101 (for example, where flexible integrated circuit 103 is spaced apart from application circuit 101 by adhesive layer 113).

Flexible integrated circuit 103 and at least one of application circuit electrical contact pads 105a, 105b may together form a trench 221a. Flexible integrated circuit 103 and application circuit electrical contact pads 105a, 105b may form a plurality of trenches 221a, 221b (for example, a respective trench between each of application circuit electrical contact pads 105a, 105b and flexible integrated circuit 103). A first trench 221a may be located between the first application circuit electrical contact pad 105a and flexible integrated circuit 103. A second trench 221b may be located between the second application circuit electrical contact pad 105b and flexible integrated circuit 103. Thus, it may be that trenches 221a, 221b are located between application circuit electrical contact pads 105a, 105b and flexible integrated circuit 103, such that application circuit electrical contact pads 105a, 105b are separated from flexible integrated circuit 103 by a width of trench 221. The width of trenches 221a, 221b may be based (at least in part) on the conductive fluid used to form solidified fluid conductors 115a, 115b (for example, depending on viscosity of the conductive fluid). The width may be based (at least in part) on a precision of a pick-and-place method or machine used in assembly of electronic circuit assembly 100. For example, the width of trenches 221a, 221b may between 1 μm and 500 μm such as, for example, between 1 μm and 100 μm, between 5 μm and 95 μm, between 10 μm and 90 μm, between 15 μm and 85 μm, between 20 μm and 80 μm, between 25 μm and 75 μm, between 30 μm and 70 μm, between 35 μm and 65 μm, or between 40 μm and 60 μm. For example, the width of trenches 221a, 221b may between 1 μm and 50 μm such as, for example, between 1 μm and 40 μm, between 1 μm and 30 μm, between 1 μm and 20 μm, between 1 μm and 10 μm. For example, the width of trenches 221a, 221b may between 100 μm and 500 μm such as, for example, between 150 μm and 450 μm, between 200 μm and 400 μm, or between 250 μm and 350 μm. It may be that a distance from a surface of application circuit 101 to the nearest application circuit connection surface 117a, 117b or integrated circuit connection surface 119a, 119b defines a depth of trenches 221a, 221b. The depth of trenches 221a, 221b may be based on one or more manufacturing constraints (for example, conductive track thickness) of application circuit 101 or flexible integrated circuit 103. For example, the depth of trenches 221a, 221b may be between 1 μm and 30 μm such as, for example, between 1.25 μm and 25 μm, between 1.5 μm and 23.5, between 1.75 μm and 23.25 μm, between 2 μm and 23 μm, between 2.25 μm and 22.75 μm, between 2.5 μm and 22.5 μm, between 2.75 μm and 22.25 μm, between 3 μm and 22 μm, between 3.25 μm and 21.75 μm, between 3.5 μm and 21.5 μm, between 3.75 μm and 21.25 μm, between 4 μm and 21.00 μm, between 4.25 μm and 20.75 μm, between 4.5 μm and 20.5 μm, between 4.75 μm and 20.25, between 5 μm and 20.00 μm. Whilst the electronic circuit assembly illustrated in FIG. 2 is shown to comprise two trenches, it will be appreciated by the skilled person that electronic circuit assemblies of the present disclosure may include any number of trenches. It may be that electronic circuit assembly 100 comprises the same number of trenches 221a, 221b as the number of application circuit electrical contact pads 105a, 105b.

At least one of solidified fluid conductors 115a, 115b may at least partially (for example, entirely) fill trenches 221a, 221b. A first solidified fluid conductor 115a may at least partially (for example, entirely) fill a first trench 221a and, optionally, a second solidified fluid conductor 115b may at least partially (for example, entirely) fill a second trench 221b. Thus, it may be that the solidified fluid conductors 115a, 115b provide electrical connection across trenches 221a, 221b, and so can be said to “bridge” each of trenches 221a, 221b. Thus, a first solidified fluid conductor 115a may bridge a first trench 221a and, optionally, a second solidified fluid conductor 115b may bridge a second trench 221b.

It will be appreciated by the skilled person that, where electronic circuit assembly 100 comprises a plurality of trenches 221a, 221b, not all of the trenches need necessarily be of the same width and/or depth. Thus, trenches 221a, 221b may have differing widths and/or depths. A first trench in the plurality may have a width that differs from that of one or more (for example, all) of the other trenches in the plurality. A first trench in the plurality may have a depth that differs from that of one or more (for example, all) of the other trenches in the plurality.

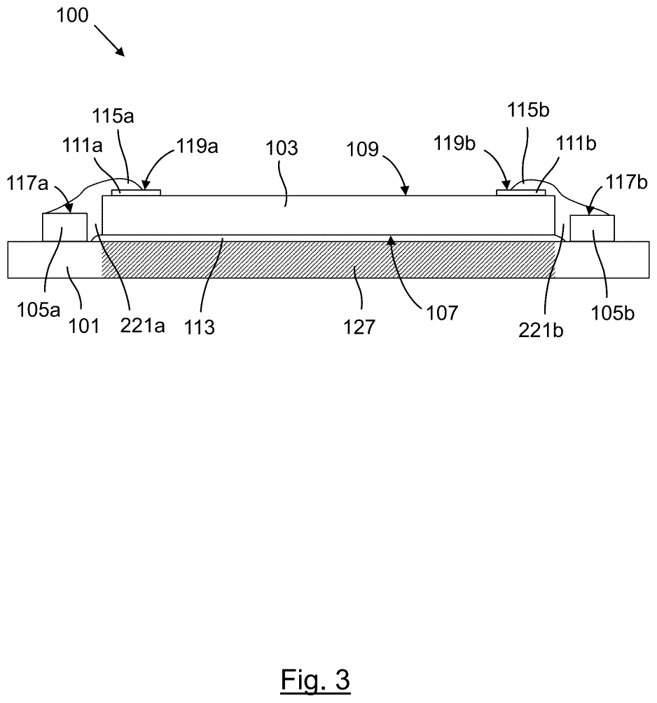

FIG. 3 shows a schematic view of an electronic circuit assembly according to the present disclosure. Application circuit connection surfaces 117a, 117b may be located within a given plane. The plane may be located between first surface 107 and second surface 109. The plane may be located between second surface 109 and application circuit 101.

The distance between first surface 107 and second surface 109 may be referred to as a height of flexible integrated circuit 103. A depth of one or more of trenches 221a, 221b may be at least 20%, at least 25%, at least 30%, at least 35%, at least 40%, at least 45%, at last 50%, at least 55%, at least 60%, at least 65%, at least 70%, or at least 75% of the height of flexible integrated circuit 103. A depth of one or more of trenches 221a, 221b may be no more than 80%, no more than 75%, no more than 70%, no more than 65%, no more than 60%, no more than 55%, or no more than 50% of the height of flexible integrated circuit 103.

One or more of application circuit electrical contact pads 105a, 105b may comprise a conductive track. Thus, application circuit 101 may comprise one or more conductive tracks (for example, forming the one or more application circuit electrical contact pads 105a, 105b).

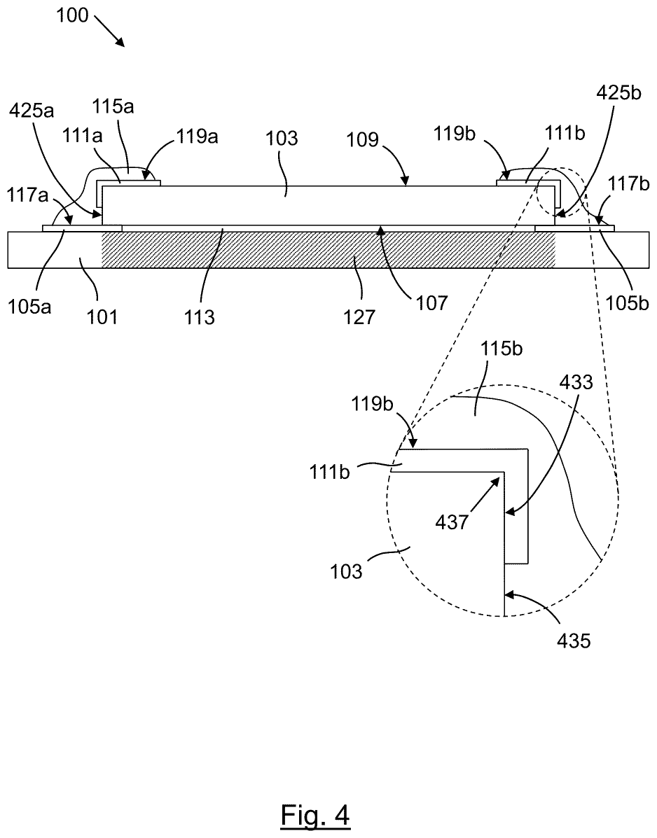

FIG. 4 shows a schematic view of an electronic circuit assembly according to the present disclosure, including a magnified portion of the electronic circuit assembly. One or more of integrated circuit electrical contact pads 111a, 111b may extend over an edge 437 of second surface 109. One or more integrated circuit electrical contact pads 111a, 111b may cover at least part of a side 425a, 425b of flexible integrated circuit 103. As previously discussed, it will be appreciated by the skilled person that integrated circuits generally have a substantially planar structure. Thus, integrated circuits generally have two larger parallel faces and four smaller narrow side faces. One of the two larger faces, referred to as a “bottom” surface, faces towards an application circuit when mounted to the application circuit. The other opposing surface (i.e. the one which faces away from the application circuit when the integrated circuit is mounted to the application circuit) is referred to as the “top” surface. The term “side” in this context refers to the four narrow faces which adjoin both the top and bottom surfaces. It will be further appreciated by the skilled person that an edge of a surface in this context refers to the boundary between two faces of the integrated circuit. Thus, edge 437 of second surface 109 refers to a boundary between second surface 109 and one of the at least four sides. These boundaries are associated with a step change in the angle of an external face of flexible integrated circuit 103. A first portion 433 of side 425a, 425b may be covered by integrated circuit electrical contact pad 111a, 111b. It may be that a second portion 435 of side 425a, 425b is not covered by integrated circuit electrical contact pad 111a, 111b. As shown in the example illustrated in FIG. 4, at least part (for example, all) of side 425a, 425b may be perpendicular to second surface 109.

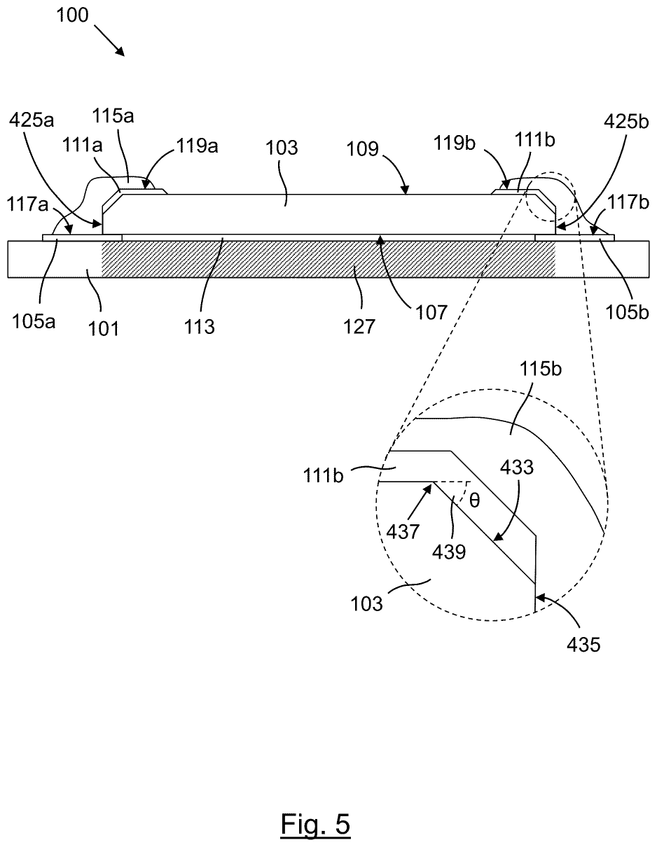

FIG. 5 shows a schematic view of an electronic circuit assembly according to the present disclosure, including a magnified portion of the electronic circuit assembly. At least part of the side 425a, 425b may be at an angle 439 from second surface 109. As shown in the example illustrated in FIG. 5, first portion 433 of side 425a, 425b may be at an angle 439 and second portion 435 of side 425a, 425b may be perpendicular to second surface 109. As shown in the example illustrated in FIG. 5, first portion 433 may be covered by integrated circuit electrical contact pad 111a, 111b. However, it will be appreciated that first portion 433 may still be offset from the plane of second surface 109 by an angle 439, but not covered by integrated circuit electrical contact pad 111a, 111b. The at least part of the side 425a, 425b may be offset from the plane of second surface 109 by an angle 439 of at least 15 degrees, at least 30 degrees, or at least 45 degrees. The at least part of the side 425a, 425b may be offset from the plane of second surface 109 by an angle 439 of no more than 75 degrees, no more than 60 degrees, or no more than 45 degrees. Thus, flexible integrated circuit 103 may comprise a sloping side 425a, 425b. A thickness of flexible integrated circuit 103 may decrease away from an edge of the second surface. A thickness of flexible integrated circuit 103 may decrease with increasing proximity to an outer periphery of flexible integrated circuit 103. The thickness may decrease smoothly (for example, linearly). It will be appreciated by the skilled person that the “thickness” of flexible integrated circuit 103 in this context refers to a distance extended by flexible integrated circuit 103 in a direction perpendicular to first surface 107. Incorporating a sloping side onto flexible integrated circuit 103 can help to provide a more conformal coating of material when constructing flexible integrated circuit 103 or when applying coatings (for example, protective coatings, conductive layers or conductive fluids) to electronic circuit assembly 100.

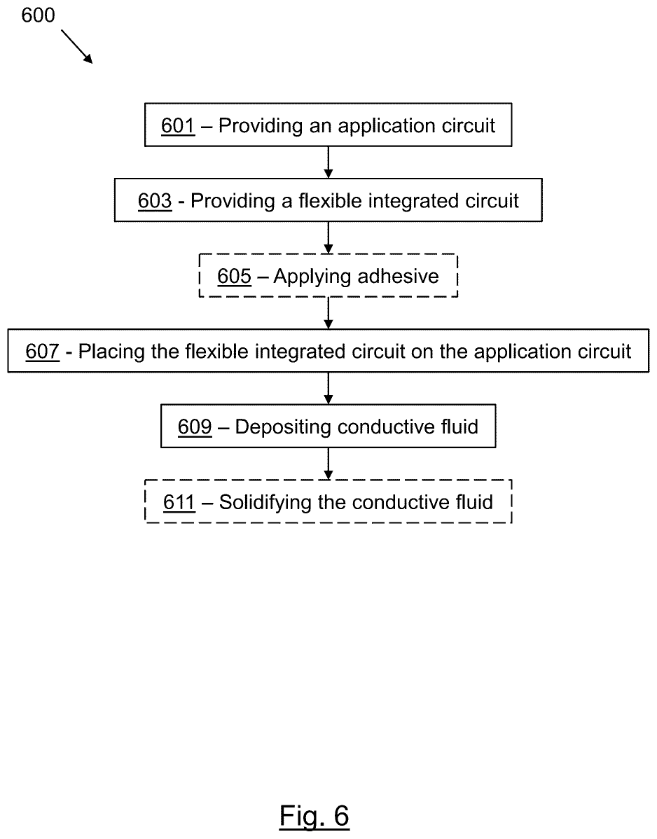

FIG. 6 shows a flow chart illustrating the steps of a method 600 of manufacturing an electronic circuit assembly according to the present disclosure.

A first step, illustrated by item 601, of method 600 comprises providing an application circuit having a plurality of application circuit electrical contact pads. The application circuit may be substantially as described above in respect of application circuit 101.

A second step, illustrated by item 603, of method 600 comprises providing a flexible integrated circuit comprising a first surface, a second surface on an opposite face of the integrated circuit to the first surface, and a plurality of integrated circuit electrical contact pads located on the second surface. The flexible integrated circuit may be substantially as described above in respect of flexible integrated circuit 103.

An optional third step, illustrated by item 605, of method 600 comprises a step for facilitating mechanical bonding the flexible integrated circuit to the application circuit 101. This step may comprise, prior to the positioning, applying adhesive to the application circuit or the flexible integrated circuit. The adhesive may comprise a non-conductive adhesive.

A fourth step, illustrated by item 607, of method 600 comprises placing the flexible integrated circuit on the application circuit such that the first surface faces the application circuit and at least part of each of the application circuit electrical contact pads is outside of a footprint of the flexible integrated circuit. One or more (for example, all) of the application circuit electrical contact pads may be partially covered by the flexible integrated circuit. One or more (for example, all) of the application circuit electrical contact pads may be entirely located outside of a footprint of the flexible integrated circuit. The placing may comprise positioning the flexible integrated circuit such that at least one of application circuit electrical contact pads and the flexible integrated circuit together form a trench.

A fifth step, illustrated by item 609, of method 600 comprises depositing conductive fluid across at least part of the second surface to electrically connect each of the integrated circuit electrical contact pads to a respective one of the application circuit electrical contact pads. The depositing may comprise depositing the conductive fluid using a syringe. The depositing may comprise printing (for example, ink-jet printing such as, for example, “bubble” or “bubble jet” printing, or screen printing) the conductive fluid. Where the method comprises a step of applying adhesive as described above, the positioning may comprise bonding the flexible integrated circuit to the application circuit using the applied adhesive. The depositing may comprise depositing conductive fluid across at least part of the second surface. Where at least one of the application circuit electrical contact pads and the flexible integrated circuit together form a trench, it may be that the depositing comprises at least partially (for example, fully) filling the trench with conductive fluid.

An optional sixth step, illustrated by item 611, of method 600 comprises solidifying the conductive fluid to form a plurality of solidified fluid conductors. The solidifying may comprise curing the conductive fluid (for example, by heat treating the conductive fluid or by exposing the conductive fluid to ultraviolet (UV) radiation).

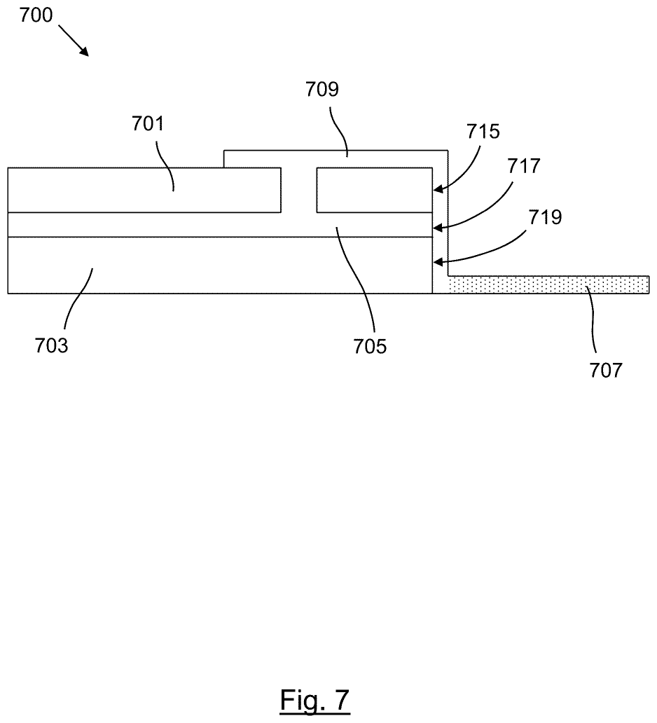

FIG. 7 shows a schematic view of a flexible integrated circuit 700 according to the present disclosure. It may be that flexible integrated circuit 700 comprises a thin-film flexible integrated circuit.

Flexible integrated circuit 700 comprises an upper dielectric layer 701, a lower dielectric layer 703, and an electrical routing layer 705. It will be appreciated by the skilled person that the terms “upper” and “lower” in this context are relative to the orientation in which flexible integrated circuit 700 is intended to be mounted to an application circuit. Thus, lower dielectric layer 703 is intended to be nearer to the application circuit than upper dielectric layer 701. Each layer of flexible integrated circuit 700 can be said to have a respective footprint. It will be appreciated by the skilled person that the “footprint” of a given layer refers in this context to the surface area of the underlying layer(s) or application circuit which is covered by the given layer.

Electrical routing layer 705 is located between upper dielectric layer 701 and lower dielectric layer 703. It will be appreciated by the skilled person that electrical routing layer 705 need not necessarily be directly adjacent to either or both of upper dielectric layer 701 and lower dielectric layer 703; there may also be additional layers (not shown) between upper dielectric layer 701 and lower dielectric layer 703 (for example, between electrical routing layer 705 and upper dielectric layer 701 and/or between electrical routing layer 705 and lower dielectric layer 703). Such additional layers may include conductive layers and/or further dielectric layers. Similarly, electrical routing layer 705 may itself comprise multiple conductive layers (not shown) and, optionally, one or more dielectric layers (not shown). Electrical routing layer 705 may provide routing of signals and power, and may also comprise electrical circuit components (for example, transistors).

Flexible integrated circuit 700 further comprises an edge connection tab 707 (the extent of which is indicated by the dot-shaded region). Edge connection tab 707 is electrically coupled to electrical routing layer 705 and protrudes beyond the footprint of the upper dielectric layer 701. As shown in the example illustrated in FIG. 7, edge connection tab 707 may consist of a single conductive layer. Thus, edge connection tab 707 may also protrude beyond the footprint of lower dielectric layer 703.

Flexible integrated circuit 700 may further comprise a top metal layer 709. Top metal layer 709 may be located on an upper surface of upper dielectric layer 701, such that that upper dielectric layer 701 is located between top metal layer 709 and electrical routing layer 705. Top metal layer 709 may extend along a side 715 of upper dielectric layer 701. Top metal layer 709 may extend along a side 717 of electrical routing layer 705 (for example, insulated from the circuitry of electrical routing layer 705 by dielectric). Top metal layer 709 may extend along a side 719 of lower dielectric layer 703. As shown in the example illustrated in FIG. 7, edge connection tab 707 may comprise an extension of top metal layer 709 beyond the footprint of upper dielectric layer 701. Top metal layer 709 may also extend beyond the footprints of electrical routing layer 705 and lower dielectric layer 703. A thickness of edge connection tab 707 may be less than a thickness of a main portion of flexible integrated circuit 700.

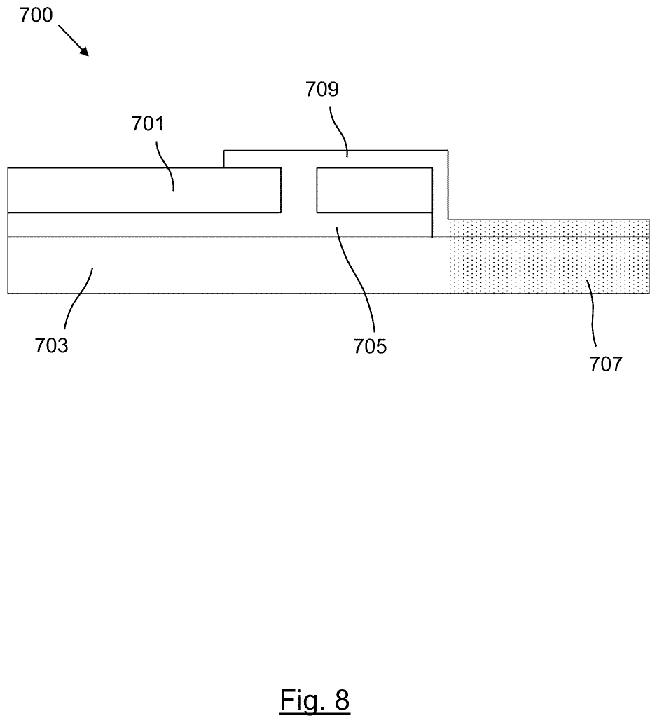

FIG. 8 shows a schematic view illustrating a flexible integrated circuit according to the present disclosure. Edge connection tab 707 may consist of a conductive layer and a dielectric layer. Edge connection tab 707 may comprise an extension of lower dielectric layer 703 beyond the footprint of upper dielectric layer 701. Thus, edge connection tab 707 may be formed by the extension of top metal layer 709 and lower dielectric layer 703 beyond the footprint of upper dielectric layer 701.

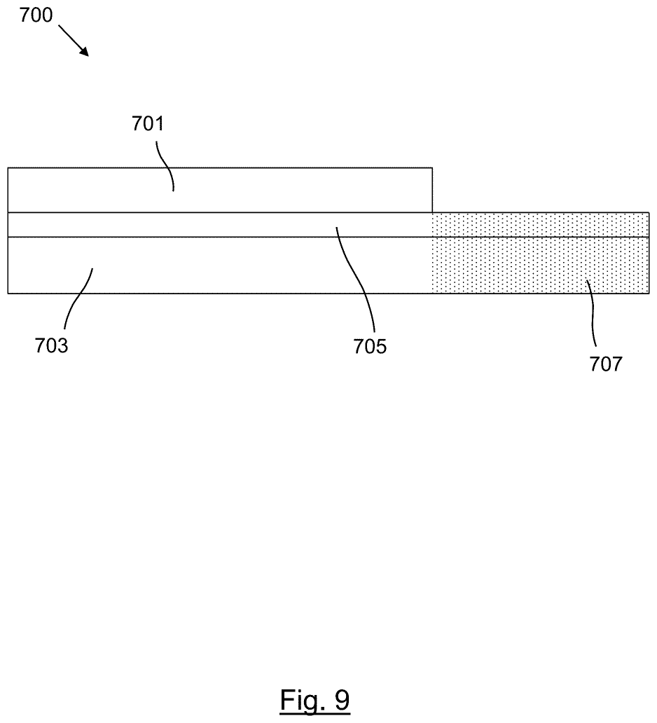

FIG. 9 shows a schematic view illustrating a flexible integrated circuit according to the present disclosure. Edge connection tab 707 may comprise an extension of at least part of electrical routing layer 705 beyond the footprint of upper dielectric layer 701. Thus, edge connection tab 707 may be formed by the extension of electrical routing layer 705 and lower dielectric layer 703 beyond the footprint of upper dielectric layer 701.

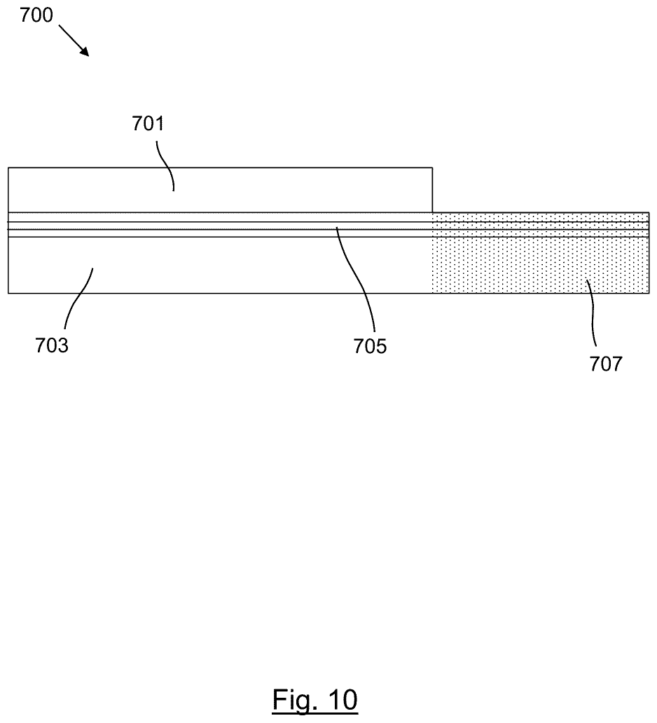

FIG. 10 shows a schematic view of a flexible integrated circuit according to the present disclosure. Electrical routing layer 705 may comprise a plurality of conductive layers. In such cases, it may be that each of the plurality of conductive layers extends beyond the footprint of upper dielectric layer 701 to form edge connection tab 707.

Providing a flexible integrated circuit with an edge connection tab may enable alternative techniques for connecting the flexible integrated circuit to an application circuit. For example, the flexible integrated circuit can be connected by pressing the edge connection tab down onto a protrusion formed on the application circuit, such that the protrusion pierces the edge connection tab. Alternatively, the edge connection tab may, for example, be used in a crimp connection.

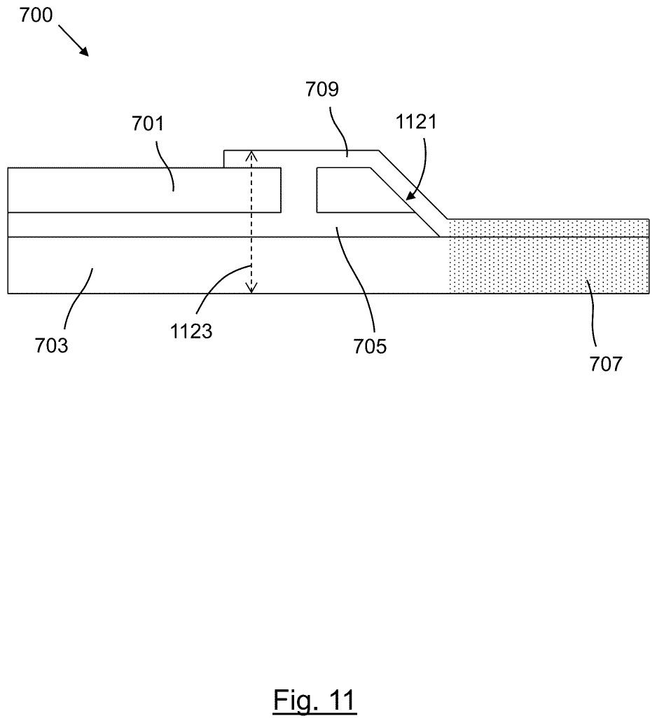

FIG. 11 shows a schematic view of a flexible integrated circuit according to the present disclosure. Flexible integrated circuit 700 may comprise a sloping side 1121 such that a thickness of flexible integrated circuit 700 decreases away from an edge of upper dielectric layer 701. The thickness (illustrated by dashed line 1123) of flexible integrated circuit 700 may decrease with increasing proximity to an outer periphery of flexible integrated circuit 700. The thickness may decrease smoothly (for example, linearly). It will be appreciated by the skilled person that the “thickness” of flexible integrated circuit 103 in this context refers to a distance extended by flexible integrated circuit 103 in a direction perpendicular to first surface 107. Top metal layer 709 may extend at least partially along (for example, along all of) sloping side 1121. Incorporating a sloping side onto flexible integrated circuit 700 may help to provide a more conformal coating of material when constructing flexible integrated circuit 700 or when applying coatings (for example, protective coatings) to flexible integrated circuit 700.

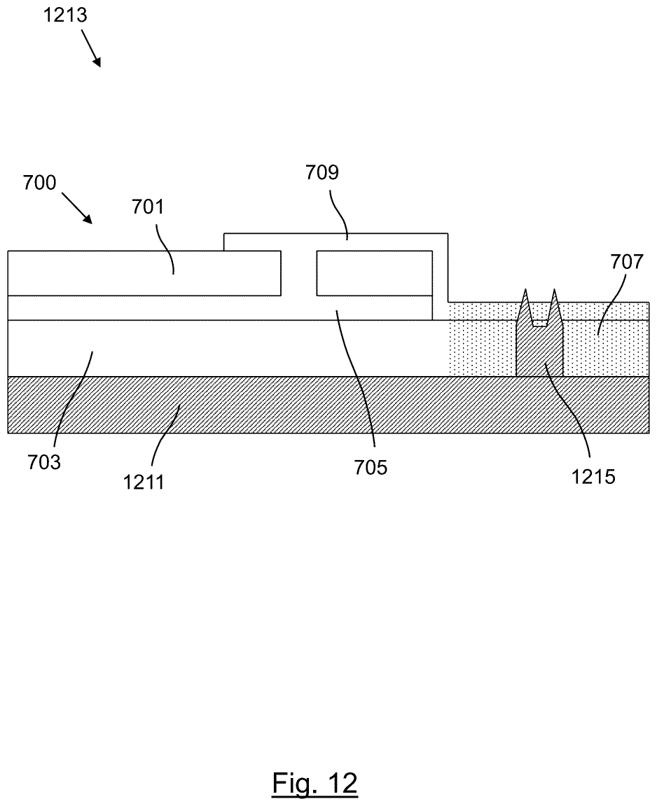

FIG. 12 shows a schematic view of an electronic circuit assembly 1213 according to the present disclosure. Flexible integrated circuit 700 may be mounted to an application circuit 1211 to form electronic circuit assembly 1213. In FIG. 12, application circuit 1211 is shown by the hatched area. Application circuit 1211 may comprise a larger circuit of which flexible integrated circuit 700 is to form part. For example, application circuit 1211 may comprise one or more of an antenna, a printed circuit board, or another flexible integrated circuit, or any other suitable application circuit. Application circuit 1211 may comprise a metal protrusion 1215 arranged such that, when the edge connection tab 707 is pressed down onto protrusion 1215, protrusion 1215 pierces edge connection tab 707, thereby electrically coupling protrusion 1215 to electrical routing layer 705. Whilst FIG. 12 shows an electronic circuit assembly in which the edge connection tab consists of extensions of top metal layer 709 and lower dielectric layer 703, it will be appreciated that other examples include electronic circuit assemblies in which the edge connection tabs consist only of an extension of top metal layer 709. Similarly, other examples include electronic circuit assemblies in which the edge connection tabs consist of extensions of electrical routing layer 705 and lower dielectric layer 703.

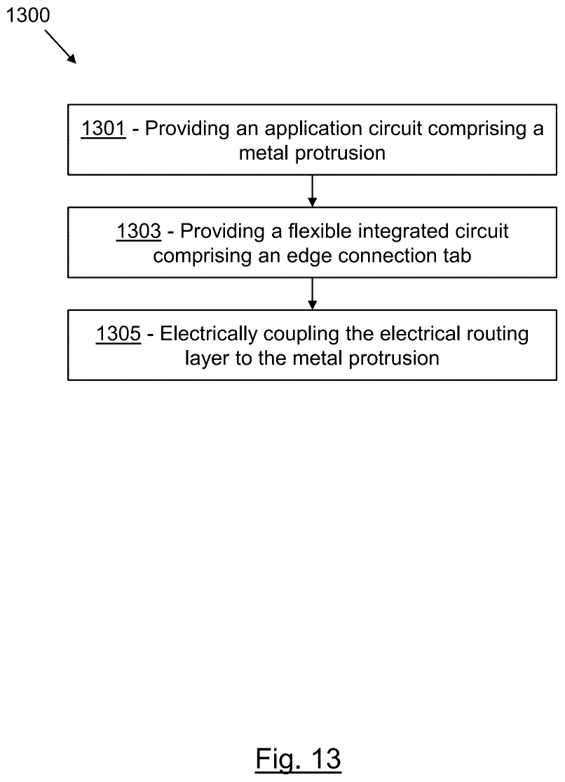

FIG. 13 shows a flow chart illustrating the steps of a method 1300 of manufacturing an electronic circuit assembly according to the present disclosure. Method 1300 provides a particularly quick and easy way of assembling a flexible integrated circuit onto an application circuit to form an electronic circuit assembly.

A first step, illustrated by item 1301, of method 1300 comprises providing an application circuit comprising a metal protrusion. The application circuit may be substantially as described above in respect of application circuit 1211.

A second step, illustrated by item 1303, of method 1300 comprises providing a flexible integrated circuit comprising: an upper dielectric layer; a lower dielectric layer; an electrical routing layer located between the upper dielectric layer and the lower dielectric layer; and an edge connection tab which is electrically coupled to the electrical routing layer and protrudes beyond a footprint of the upper dielectric layer. The flexible integrated circuit may be substantially as described above in respect of flexible integrated circuit 700.

A third step, illustrated by item 1305, of method 1300 comprises electrically coupling the electrical routing layer to the metal protrusion by pressing the edge connection tab down onto the protrusion. Pressing the edge connection tab down onto the protrusion may comprise causing the protrusion to pierce the edge connection tab. Pressing the edge connection tab down onto the protrusion may comprise electrically connecting the protrusion to the edge connection tab.

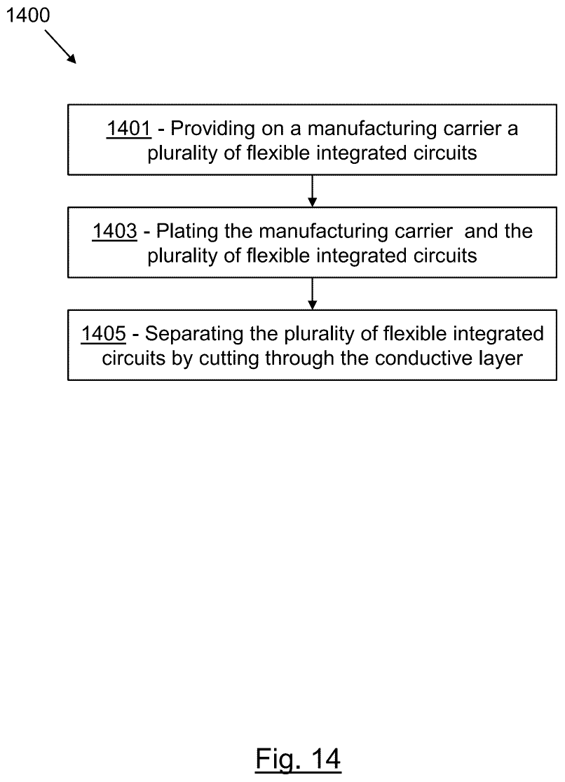

FIG. 14 shows a flow chart illustrating the steps of a method 1400 of manufacturing flexible integrated circuits according to the present disclosure. Method 1400 may provide a particularly efficient way of manufacturing a plurality of flexible integrated circuits having edge connection tabs.

A first step, illustrated by item 1401, of method 1400 comprises providing on a manufacturing carrier a plurality of flexible integrated circuits. Each of the flexible integrated circuits comprises an upper dielectric layer, a lower dielectric layer, and an electrical routing layer located between the upper dielectric layer and the lower dielectric layer. The plurality of flexible integrated circuits may be spaced apart on the manufacturing carrier. The manufacturing carrier may comprise a glass carrier. Thus, it may be that providing the plurality of flexible integrated circuits comprises manufacturing the plurality of flexible integrated circuits on the manufacturing carrier. The providing may comprise depositing one or more layers of thin-film polymer onto the manufacturing carrier. The providing may comprise depositing one or more layers of conductive material (for example, onto one or more of the layers of thin-film polymer). It may be that the providing comprises forming one or more flexible integrated circuit electrical contact pads (for example, by patterning metal contact areas onto one or more of the layers of thin film polymer). The providing may comprise forming one or more vias (for example, through the one or more layers of thin-film polymer). Forming the one or more vias may comprise etching (for example, using oxygen plasma dry etch after photo-resist patterning) and filling (for example, by electro/electro-less plating techniques) the one or more vias. Alternatively or additionally, one or more of the vias may be formed using mechanical processes.

A second step, illustrated by item 1403, of method 1400 comprises plating the manufacturing carrier and the plurality of flexible integrated circuits with a conductive layer. The manufacturing carrier may be formed from glass, polycarbonate, quartz, silicon, or any other suitable material. Thus, the method may comprise fabricating a plurality of flexible integrated circuits on the manufacturing carrier (for example, on a rigid glass carrier). The plating process may be achieved may using thin-film processes selected from one or more of:
physical vapour deposition (e.g. sputter), chemical vapour deposition (e.g. plasma-enhanced chemical vapour deposition (PECVD)), vacuum deposition (e.g. thermal or electron-beam evaporation); coating (e.g. spin, dip, blade, bar, spray, or slot-die), printing (e.g. jet, gravure, offset, screen, or flexographic), pulsed-laser deposition (PLD), atomic layer deposition (ALD) and/or any other suitable processes. Patterning of deposited materials may be performed using lithographic processes such as, for example: photolithography, electron-beam lithography, X-ray lithography, or ion-beam lithography; printing and/or other known processes. Patterning may be combined with one or more of: wet etching, dry etching (e.g. plasma etching), ablation, milling, lift-off patterning, and any other known processes. For example, the plating process may be achieved using thin-film processes selected from one or more of Atomic Layer Deposition (ALD), directional Physical Vapour Deposition (PVD) and photolithography.

A third step, illustrated by item 1405, of method 1400 comprises separating the plurality of flexible integrated circuits by cutting through the conductive layer between the flexible integrated circuits. The spacing of the plurality of flexible integrated circuits on the manufacturing carrier is such that the cutting forms, on each of the flexible integrated circuits, an edge connection tab comprising an extension of the conductive layer beyond a footprint of the respective upper dielectric layer. Cutting the conductive layer may comprise dicing the plurality of flexible integrated circuits. Cutting may comprise one or more of scribing and breaking, mechanical sawing, and laser cutting, or any other suitable process, tool or technique.

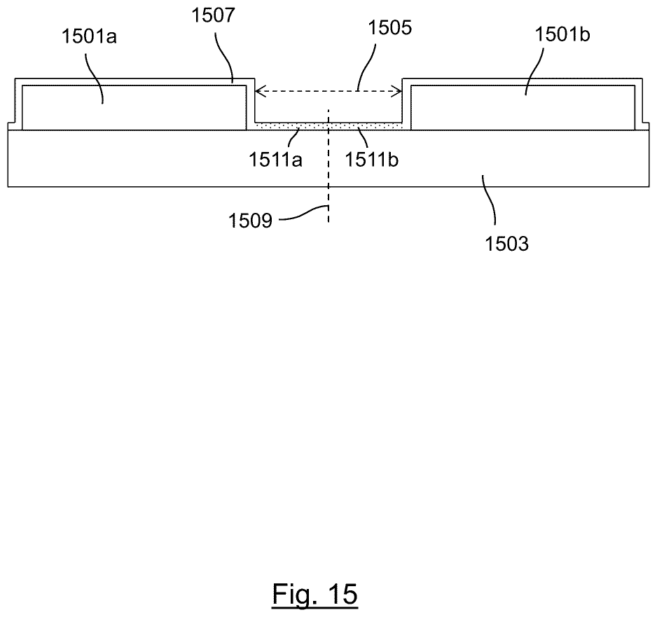

FIG. 15 shows a schematic view of an intermediate stage in the method of FIG. 14. A plurality of flexible integrated circuits 1501a, 1501b are mounted on a manufacturing carrier 1503. Flexible integrated circuits 1501a, 1501b are spaced apart such that there is an inter-IC space 1505 between each of flexible integrated circuits 1501a, 1501b. Flexible integrated circuits 1501a, 1501b and manufacturing carrier 1503 have been metal plated, such that a conductive layer 1507 now covers the exposed surfaces of flexible integrated circuits 1501a, 1501b and manufacturing carrier 1503. Separating flexible integrated circuits 1501a, 1501b by cutting through conductive layer 1507 at the location indicated by dashed line 1509 results (once the manufacturing carrier is subsequently removed) in the formation of at least two metal coated flexible integrated circuits, each having an edge connection tab 1511a, 1511b consisting of a single conductive layer or a single electrical routing layer (for example, as described above in respect of flexible integrated circuit 700). The extent of edge connection tabs 1511a, 1511b is indicated in FIG. 15 by the dot-shaded regions.

Whilst the present disclosure has been described and illustrated with reference to particular embodiments or examples, it will be appreciated by those of ordinary skill in the art that the disclosure lends itself to many different variations not specifically illustrated herein. By way of example only, certain possible variations will now be described.

The electronic circuit assemblies described above include electronic circuit assemblies in which a flexible integrated circuit is electrically connected to an application circuit by solidified fluid conductors. Such electronic circuit assemblies as described above include a plurality of integrated circuit electrical contact pads and a plurality of application circuit electrical contact pads. It will be appreciated by the skilled person that other electrical contact pads may additionally be present on one or both of the flexible integrated circuit and the application circuit. The flexible integrated circuit may comprise a plurality of further integrated circuit electrical contact pads (for example, located on the first surface of the flexible integrated circuit). The application circuit may comprise a plurality of further application circuit electrical contact pads (for example, located within the footprint of the flexible integrated circuit). In such cases, it may be that the further integrated circuit electrical contact pads are electrically connected to the further application circuit electrical contact pads. The electrical connection may, for example, be provided by conventional means (i.e. not by the use of solidified fluid conductors).

The present disclosure further provides a flexible integrated circuit comprising:
an upper dielectric layer;
a lower dielectric layer;
a metal routing layer positioned between the upper dielectric layer and the lower dielectric layer; and
a top metal layer which is located on an upper surface of the integrated circuit such that the upper dielectric layer is between the top metal layer and the metal routing layer, the top metal layer being electrically coupled to the metal routing layer and extending over an upper edge of the integrated circuit and, at least partly, down the side of the integrated circuit.

The present disclosure further provides an electronic circuit assembly comprising:
a flexible integrated circuit comprising:
   an upper dielectric layer;
   a lower dielectric layer;
   a metal routing layer positioned between the upper dielectric layer and the lower dielectric layer; and
   a top metal layer which is located on an upper surface of the integrated circuit such that the upper dielectric layer is between the top metal layer and the metal routing layer, the top metal layer being electrically coupled to the metal routing layer and extending over an upper edge of the integrated circuit and, at least partly, down the side of the integrated circuit; and
   an application circuit comprising a connector clamped onto the side of the flexible integrated circuit such that the connector is in contact with the extension of the top metal layer onto the side.

The present disclosure further provides a method of connecting a flexible integrated circuit to an application circuit, the method comprising:
providing a flexible integrated circuit comprising:
an upper dielectric layer;
a lower dielectric layer;
a metal routing layer positioned between the upper dielectric layer and the lower dielectric layer; and
a top metal layer which is located on an upper surface of the integrated circuit such that the upper dielectric layer is between the top metal layer and the metal routing layer, the top metal layer being electrically coupled to the metal routing layer and extending over an upper edge of the integrated circuit and, at least partly, down the side of the integrated circuit;
providing an application circuit comprising a connector arranged to clamp onto the side of the flexible integrated circuit;
placing the flexible integrated circuit onto the application circuit; and
electrically connecting the flexible integrated circuit to the application circuit by clamping the connector onto the side of the flexible integrated circuit such that the connector is in contact with the extension of the top metal layer onto the side.

Such a method may provide zero insertion force connection of the flexible integrated circuit to the application circuit.

Where in the foregoing description, integers or elements are mentioned which have known, obvious or foreseeable equivalents, then such equivalents are herein incorporated as if individually set forth. Reference should be made to the claims for determining the true scope of the present disclosure, which should be construed so as to encompass any such equivalents. It will also be appreciated by the reader that integers or features of the disclosure that are described as preferable, advantageous, convenient or the like are optional and do not limit the scope of the independent claims. Moreover, it is to be understood that such optional integers or features, whilst of possible benefit in some embodiments of the disclosure, may not be desirable, and may therefore be absent, in other embodiments.
Clause 1. An electronic circuit assembly comprising: an application circuit comprising a plurality of application circuit electrical contact pads; and a flexible integrated circuit comprising a first surface, a second surface on an opposite face of the flexible integrated circuit to the first surface, and a plurality of integrated circuit electrical contact pads located on the second surface; wherein: the flexible integrated circuit is arranged such that the first surface faces the application circuit and each of the application circuit electrical contact pads is located at least partially outside of a footprint of the flexible integrated circuit; and each of the integrated circuit electrical contact pads is electrically connected to a respective one of the application circuit electrical contact pads by a respective one of a plurality of solidified fluid conductors.
Clause 2. An electronic circuit assembly according to clause 1, wherein one or more of the plurality of solidified fluid conductors extends across at least part of the second surface.
Clause 3. An electronic circuit assembly according to clause 1 or 2, wherein the solidified fluid conductors have been formed by depositing conductive fluid.
Clause 4. An electronic circuit assembly according to any preceding clause, wherein one or more of the application circuit electrical contact pads are located partially within the footprint of the flexible integrated circuit.
Clause 5. An electronic circuit assembly according to any preceding clause, wherein: each of the application circuit electrical contact pads comprises an application circuit connection surface; each of the integrated circuit electrical contact pads comprises an integrated circuit connection surface; and the respective solidified fluid conductor connects each of the application circuit electrical contact pads to the respective integrated circuit electrical contact pad via the application circuit connection surface and the integrated circuit connection surface.
Clause 6. An electronic circuit assembly according to clause 5, wherein, for one or more of the application circuit electrical contact pads, the application circuit connection surface is substantially coplanar with the integrated circuit connection surface.
Clause 7. An electronic circuit assembly according to clause 5 or 6, wherein, for one or more of the application circuit electrical contact pads, a plane of the application circuit connection surface is located towards the application circuit from the second surface.
Clause 8. An electronic circuit assembly according to any of clauses 5 to 7, wherein, for one or more of the application circuit electrical contact pads, a plane of the application circuit connection surface is located between the first surface and the second surface.
Clause 9. An electronic circuit assembly according to any of clauses 5 to 8, wherein, for one or more of the application circuit electrical contact pads, the application circuit connection surface is substantially coplanar with the first surface.
Clause 10. An electronic circuit assembly according to any preceding clause, wherein: at least one of the application circuit electrical contact pads and the flexible integrated circuit together form a trench; and at least one of the solidified fluid conductors at least partially fills the trench.
Clause 11. An electronic circuit assembly according to any preceding clause, wherein one or more of the integrated circuit electrical contact pads extends over an edge of the second surface and covers at least part of a side of the flexible integrated circuit.
Clause 12. An electronic circuit assembly according to clause 11, wherein at least part of the side of the flexible integrated circuit is perpendicular to the second surface.
Clause 13. An electronic circuit assembly according to clause 11 or 12, wherein at least part of the side of the flexible integrated circuit is at an angle of less than 90° from the second surface.
Clause 14. An electronic circuit assembly according to any preceding clause, wherein the flexible integrated circuit comprises a sloping side such that a thickness of the flexible integrated circuit decreases away from an edge of the second surface.
Clause 15. An electronic circuit assembly according to any preceding clause, wherein the flexible integrated circuit comprises a thin-film flexible integrated circuit.
Clause 16. A method of manufacturing an electronic circuit assembly, the method comprising: providing an application circuit having a plurality of application circuit electrical contact pads; providing a flexible integrated circuit comprising a first surface, a second surface on an opposite face of the integrated circuit to the first surface, and a plurality of integrated circuit electrical contact pads located on the second surface; positioning the flexible integrated circuit on the application circuit such that the first surface faces the application circuit and at least part of each of the application circuit electrical contact pads is outside of a footprint of the flexible integrated circuit; and depositing conductive fluid across at least part of the second surface to electrically connect each of the integrated circuit electrical contact pads to a respective one of the application circuit electrical contact pads.
Clause 17. A method according to clause 16 wherein the depositing comprises one or more of: depositing the conductive fluid using a syringe, depositing the conductive fluid by printing, and depositing the conductive fluid using direct write processes.
Clause 18. A method according to any of clauses 16 or 17, further comprising curing the conductive fluid to form a plurality of solidified fluid conductors
Clause 19. A method according to any of clauses 16 to 18, wherein: the method further comprises, prior to the positioning, applying adhesive to the application circuit or the flexible integrated circuit; and the positioning comprises bonding the flexible integrated circuit to the application circuit using the applied adhesive.
Clause 20. A flexible integrated circuit comprising: an upper dielectric layer; a lower dielectric layer; an electrical routing layer located between the upper dielectric layer and the lower dielectric layer; and an edge connection tab which is electrically coupled to the electrical routing layer and protrudes beyond a footprint of the upper dielectric layer.
Clause 21. A flexible integrated circuit according to clause 20, wherein the edge connection tab consists of a single conductive layer.
Clause 22. A flexible integrated circuit according to clause 20, wherein the edge connection tab consists of a conductive layer and a dielectric layer.
Clause 23. A flexible integrated circuit according to clause 20 or 22, wherein the edge connection tab comprises an extension of the lower dielectric layer beyond the footprint of the upper dielectric layer.
Clause 24. A flexible integrated circuit according to any of clauses 20 to 23, wherein the flexible integrated circuit comprises a top metal layer located on an upper surface of the upper dielectric layer, such that the upper dielectric layer is located between the top metal layer and the electrical routing layer.
Clause 25. A flexible integrated circuit according to clause 24, wherein: the top metal layer extends along a side of the upper dielectric layer; and the edge connection tab comprises an extension of the top metal layer beyond the footprint of the upper dielectric layer.
Clause 26. A flexible integrated circuit according to any of clauses 20 to 25, wherein the edge connection tab comprises an extension of the electrical routing layer beyond the footprint of the upper dielectric layer.
Clause 27. A flexible integrated circuit according to any of clauses 20 to 25, wherein the flexible integrated circuit comprises a sloping side such that a thickness of the flexible integrated circuit decreases away from an edge of upper dielectric layer.
Clause 28. A flexible integrated circuit according to clauses 24 and 27, wherein the top metal layer extends at least partially along the sloping side.
Clause 29. A flexible integrated circuit according to any of clauses 20 to 28, wherein the flexible integrated circuit comprises a thin-film flexible integrated circuit.
Clause 30. An electronic circuit assembly comprising: an integrated circuit according to any of claims 20 to 29; and an application circuit comprising a metal protrusion arranged such that, when the edge connection tab is pressed down onto the protrusion, the protrusion pierces the edge connection tab, so as to electrically couple the protrusion to the electrical routing layer.
Clause 31. A method of manufacturing an electronic circuit assembly, the method comprising: providing an application circuit comprising a metal protrusion; providing a flexible integrated circuit comprising: an upper dielectric layer; a lower dielectric layer; an electrical routing layer located between the upper dielectric layer and the lower dielectric layer; and an edge connection tab which is electrically coupled to the electrical routing layer and protrudes beyond a footprint of the upper dielectric layer; and electrically coupling the electrical routing layer to the metal protrusion by pressing the edge connection tab down onto the protrusion.
Clause 32. A method of manufacturing flexible integrated circuits, the method comprising: providing on a manufacturing carrier a plurality of flexible integrated circuits, each of the flexible integrated circuits comprising an upper dielectric layer, a lower dielectric layer, and an electrical routing layer located between the upper dielectric layer and the lower dielectric layer; plating the manufacturing carrier and the plurality of flexible integrated circuits with a conductive layer; and separating the plurality of flexible integrated circuits by cutting through the conductive layer between the flexible integrated circuits, wherein the plurality of flexible integrated circuits are spaced apart on the manufacturing carrier such that the cutting forms, on each of the flexible integrated circuits, an edge connection tab comprising an extension of the conductive layer beyond a footprint of the respective upper dielectric layer.

What is claimed is:

1. An electronic circuit assembly comprising:
an application circuit comprising a plurality of application circuit electrical contact pads; and
a flexible integrated circuit comprising a first surface, a second surface on an opposite face of the flexible integrated circuit to the first surface, and a plurality of integrated circuit electrical contact pads located on the second surface;
wherein:
the flexible integrated circuit is arranged such that the first surface faces the application circuit and each of the plurality of application circuit electrical contact pads is located at least partially outside of a footprint of the flexible integrated circuit; and
each of the plurality of integrated circuit electrical contact pads is electrically connected to a respective one of the plurality of application circuit electrical contact pads by a respective one of a plurality of solidified fluid conductors.

2. The electronic circuit assembly according to claim 1, wherein one or more of the plurality of solidified fluid conductors extends across at least part of the second surface.

3. The electronic circuit assembly according to claim 1, wherein the plurality of solidified fluid conductors have been formed by depositing conductive fluid.

4. The electronic circuit assembly according to claim 1, wherein one or more of the plurality of application circuit electrical contact pads are located partially within the footprint of the flexible integrated circuit.

5. The electronic circuit assembly according to claim 1, wherein:
each of the plurality of application circuit electrical contact pads comprises an application circuit connection surface;
each of the plurality of integrated circuit electrical contact pads comprises an integrated circuit connection surface; and
the respective solidified fluid conductor connects each of the plurality of application circuit electrical contact pads to the respective integrated circuit electrical contact pad via the application circuit connection surface and the integrated circuit connection surface.

6. The electronic circuit assembly according to claim 5, wherein, for one or more of the plurality of application circuit electrical contact pads, at least one of:
the application circuit connection surface is substantially coplanar with the integrated circuit connection surface;
a plane of the application circuit connection surface is located towards the application circuit from the second surface;
a plane of the application circuit connection surface is located between the first surface and the second surface; or
the application circuit connection surface is substantially coplanar with the first surface.

7. The electronic circuit assembly according to claim 1, wherein:
at least one of the plurality of application circuit electrical contact pads or the flexible integrated circuit forms a trench; and
at least one of the plurality of solidified fluid conductors at least partially fills the trench.

8. The electronic circuit assembly according to claim 1, wherein one or more of the plurality of integrated circuit electrical contact pads extends over an edge of the second surface and covers at least part of a side of the flexible integrated circuit.

9. The electronic circuit assembly according to claim 8, wherein:
at least part of the side of the flexible integrated circuit is perpendicular to the second surface; or
at least part of the side of the flexible integrated circuit is at an angle of less than 90° from the second surface.

10. The electronic circuit assembly according to claim 1, wherein at least one of:
the flexible integrated circuit comprises a sloping side such that a thickness of the flexible integrated circuit decreases away from an edge of the second surface; or
the flexible integrated circuit comprises a thin-film flexible integrated circuit.

11. A flexible integrated circuit comprising:
an upper dielectric layer;
a lower dielectric layer;
an electrical routing layer located between the upper dielectric layer and the lower dielectric layer; and
an edge connection tab which is electrically coupled to the electrical routing layer and protrudes beyond a footprint of the upper dielectric layer.

12. The flexible integrated circuit according to claim 11, wherein the edge connection tab consists of:
a single conductive layer; or
a conductive layer and a dielectric layer.

13. The flexible integrated circuit according to claim 11, wherein the edge connection tab comprises an extension of the lower dielectric layer beyond the footprint of the upper dielectric layer.

14. The flexible integrated circuit according to claim 11, wherein the flexible integrated circuit comprises a top metal layer located on an upper surface of the upper dielectric layer, such that the upper dielectric layer is located between the top metal layer and the electrical routing layer.

15. The flexible integrated circuit according to claim 14, wherein:
the top metal layer extends along a side of the upper dielectric layer; and
the edge connection tab comprises an extension of the top metal layer beyond the footprint of the upper dielectric layer.

16. The flexible integrated circuit according to claim 11, wherein the edge connection tab comprises an extension of the electrical routing layer beyond the footprint of the upper dielectric layer.

17. The flexible integrated circuit according to claim 11, wherein the flexible integrated circuit comprises a sloping side such that a thickness of the flexible integrated circuit decreases away from an edge of the upper dielectric layer.

18. The flexible integrated circuit according to claim 14, wherein the flexible integrated circuit comprises a sloping side such that a thickness of the flexible integrated circuit decreases away from an edge of upper dielectric layer, and wherein the top metal layer extends at least partially along the sloping side.

19. The flexible integrated circuit according to claim 11, wherein the flexible integrated circuit comprises a thin-film flexible integrated circuit.

20. An electronic circuit assembly comprising:
an integrated circuit comprising:
an upper dielectric layer;
a lower dielectric layer;
an electrical routing layer located between the upper dielectric layer and the lower dielectric layer; and
an edge connection tab which is electrically coupled to the electrical routing layer and protrudes beyond a footprint of the upper dielectric layer; and
an application circuit comprising a metal protrusion arranged such that, when the edge connection tab is pressed down onto the metal protrusion, the metal protrusion pierces the edge connection tab, so as to electrically couple the metal protrusion to the electrical routing layer.
